(19) United States
(12) Patent Application Publication
(10) Pub. No.: US 2019/0341504 A1
(43) Pub. Date: Nov. 7, 2019

(54) SEMICONDUCTOR DEVICE AND METHOD OF MANUFACTURING THE SAME

(71) Applicants: Hyundai Motor Company, Seoul (KR); Kia Motors Corporation, Seoul (KR)

(72) Inventors: NackYong Joo, Hanam-si (KR); Youngkyun Jung, Seoul (KR); Junghee Park, Suwon-si (KR); JongSeok Lee, Suwon-si (KR); Dae Hwan Chun, Gwangmyeong-si (KR)

(73) Assignees: Hyundai Motor Company, Seoul (KR); Kia Motors Corporation, Seoul (KR)

(21) Appl. No.: 16/165,885

(22) Filed: Oct. 19, 2018

(30) Foreign Application Priority Data
May 4, 2018 (KR) 10-2018-0051815

(51) Int. Cl. H01L 29/872; H01L 29/06; H01L 29/08; H01L 29/47

(52) U.S. Cl. CPC H01L 29/872; H01L 29/0623; H01L 29/47; H01L 29/0847; H01L 29/0834

(57) ABSTRACT

A semiconductor device may include an n− type of layer disposed at a first surface of a substrate; a p− type of region and a p+ type of region disposed at a top portion of the n− type of layer; a first electrode disposed on the p− type of region and the p+ type of region; and a second electrode disposed at a second surface of the substrate, wherein the first electrode includes a first metal layer disposed on the p− type of region and a second metal layer disposed on the first metal layer, and the first metal layer is in continuous contact with the p− type of region.

### CROSS-REFERENCE TO RELATED APPLICATION

The present application claims priority to Korean Patent Application No. 10-2018-0051815 filed on May 4, 2018, the entire contents of which is incorporated herein for all purposes by this reference.

### BACKGROUND OF THE INVENTION

### Field of the Invention

The present invention relates to a semiconductor device including silicon carbide (SiC), and a manufacturing method thereof.

### Description of Related Art

Following the recent trend of appliances becoming larger and having larger capacity, the demand for power semiconductor devices having a high breakdown voltage with high current and high-speed switching is increasing. A silicon carbide (SiC) power device that has been pointed out as the only device that can satisfy the above-described characteristic due to its superior characteristics with respect to a conventional silicon (Si) device is currently being actively researched and is in an early stage of market entry.

In a case of a SiC PiN diode, aspects that are suitable for a SiC diode element exist due to high turn-on voltage and slow switching speed as a characteristic of a bipolar element.

Therefore, most SiC diodes currently mass-produced have a SiC Schottky Barrier Diode (SBD) structure, and to improve a leakage current characteristic of the SBD, a Junction Barrier Schottky (JBS) structure in which p+ type of region is formed as an ion injection type in a bottom end of a Schottky junction part has been provided.

The information disclosed in this Background of the Invention section is only for enhancement of understanding of the general background of the invention and may not be taken as an acknowledgement or any form of suggestion that this information forms the prior art already known to a person skilled in the art.

### BRIEF SUMMARY

Various aspects of the present invention are directed to providing a silicon carbide diode having low leakage current and high current density.

A semiconductor device may include an n− type of layer disposed at a first surface of a substrate; a p− type of region and a p+ type of region disposed at a top portion of the n− type of layer; a first electrode disposed on the p− type of region and the p+ type of region; and a second electrode disposed at a second surface of the substrate, wherein the first electrode may include a first metal layer disposed on the p− type of region and a second metal layer disposed on the first metal layer, and the first metal layer is in continuous contact with the p− type of region.

An ion doping concentration of the p+ type of region may be higher than an ion doping concentration of the p− type of region.

The p− type of region and the p+ type of region may be in contact with each other.

The thickness of the p+ type of region may be thicker than the thickness of the p− type of region.

The first metal layer may include a Schottky metal, and the second metal layer and the second electrode may include an ohmic metal.

The first metal layer may be disposed and extended on the p+ type of region.

The first metal layer may be in contact with the p− type of region to form a Schottky junction in the boundary surface therebetween, and may be in contact with the p+ type of region to form an ohmic junction in the boundary surface therebetween.

The second metal layer may be disposed on the p+ type of region.

The first metal layer may be in contact with the p− type of region to form the Schottky junction in the boundary surface therebetween, and the second metal layer may be in contact with the p+ type of region to form the ohmic junction in the boundary surface therebetween.

The substrate may be an n+ type of silicon carbide substrate.

A manufacturing method of a semiconductor device may include forming an n− type of layer in a first surface of a substrate; forming a p− type of region and a p+ type of region in a top portion of the n− type of layer; forming a first electrode on the p− type of region and the p+ type of region; and forming a second electrode in a second surface of the substrate, wherein the first electrode may include a first metal layer disposed on the p− type of region and a second metal layer disposed on the first metal layer, and the first metal layer is in continuous contact with the p− type of region.

According to an exemplary embodiment of the present invention, the semiconductor device increases a current density in the on state and decreases a leakage current in the off state.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a schematic view showing an example of a cross-section of a semiconductor device according to an exemplary embodiment of the present invention.

FIG. 2A, FIG. 2B, FIG. 3A and FIG. 3B are views showing an operation of the semiconductor device according to FIG. 1.

FIG. 4, FIG. 5, and FIG. 6 are views schematically showing an example of a manufacturing method of a semiconductor device according to an exemplary embodiment of the present invention.

FIG. 7 is a schematic view showing an example of a cross-section of a semiconductor device according to various exemplary embodiments of the present invention.

It may be understood that the appended drawings are not necessarily to scale, presenting a somewhat simplified representation of various features illustrative of the basic principles of the invention. The specific design features of the present invention as included herein, including, for example, specific dimensions, orientations, locations, and shapes will be determined in part by the particularly intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the other hand, the invention(s) is/are intended to cover not only the exemplary embodiments, but also various alternatives, modifications, equivalents and other embodiments, which may be included within the spirit and scope of the invention as defined by the appended claims.

Hereinafter, various exemplary embodiments of the present invention will be described in detail with reference to the accompanying drawings. As those skilled in the art would realize, the described embodiments may be modified in various different ways, all without departing from the spirit or scope of the present invention. On the other hand, the introduced embodiments are provided to make included contents thorough and complete and to sufficiently deliver the spirit of the present invention to those skilled in the art.

In the drawings, the thickness of layers, films, panels, regions, etc., are exaggerated for clarity. It will be understood that when a layer is referred to as being “on” another layer or substrate, it may be directly on the other layer or substrate, or a further layer or substrate intervening them may also be present.

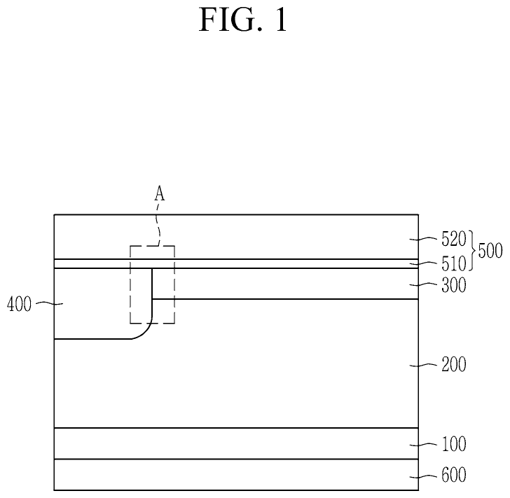

FIG. 1 is a schematic view showing an example of a cross-section of a semiconductor device according to an exemplary embodiment of the present invention.

Referring to FIG. 1, the semiconductor device according to the present exemplary embodiment includes a substrate 100, an n− type of layer 200, a p− type of region 300, a p+ type of region 400, a first electrode 500, and a second electrode 600.

The semiconductor device according to the present exemplary embodiment of the present invention may be a diode. In the instant case, the first electrode 500 may be an anode and the second electrode 600 may be a cathode.

The substrate 100 may be an n+ type of silicon carbide substrate.

The n− type of layer 200 is disposed on a first surface of the substrate 100.

The p− type of region 300 and the p+ type of region 400 are disposed on the n− type of layer 200. The p− type of region 300 and the p+ type of region 400 are in contact with each other. Here, as the p− type of region 300 and the n− type of layer 200 are in contact with each other, a PN junction is formed in a boundary surface thereof.

An ion doping concentration of the p+ type of region 400 is higher than an ion doping concentration of the p− type of region 300. Also, a thickness of the p+ type of region 400 is thicker than a thickness of the p− type of region 300. However, it is not limited thereto, and the thickness of the p+ type of region 400 may be the same as the thickness of the p− type of region 300.

The first electrode 500 is disposed on the p− type of region 300 and the p+ type of region 400, and includes a first metal layer 510 and a second metal layer 520. The first metal layer 510 may include a Schottky metal, and the second metal layer 520 may include an ohmic metal.

The first metal layer 510 is disposed on the p− type of region 300 and the p+ type of region 400, and the second metal layer 520 is disposed on the first metal layer 510. Here, the first metal layer 510 is in contact with the p− type of region 300, a Schottky junction is formed in the boundary surface therebetween. Also, the first metal layer 510 is in contact with the p+ type of region 400, and an ohmic junction is formed in the boundary surface therebetween. The first metal layer 510 and the p− type of region 300 are in continuous contact. That is, the first metal layer 510 is not in contact with the n− type of layer 200.

The second electrode 600 is disposed on a second surface of the substrate 100. Here, the second surface of the substrate 100 indicates a side opposite to the first surface of the substrate 100. The second electrode 600 may include the ohmic metal.

In the semiconductor device according to the exemplary embodiment of the present invention, two internal electric fields are formed due to the Schottky junction and the PN junction in the state that the voltage is not applied.

The internal electric field due to the Schottky junction is reinforced by the external electric field in the on state, and the internal electric field due to the PN junction is reinforced by the external electric field in the off state.

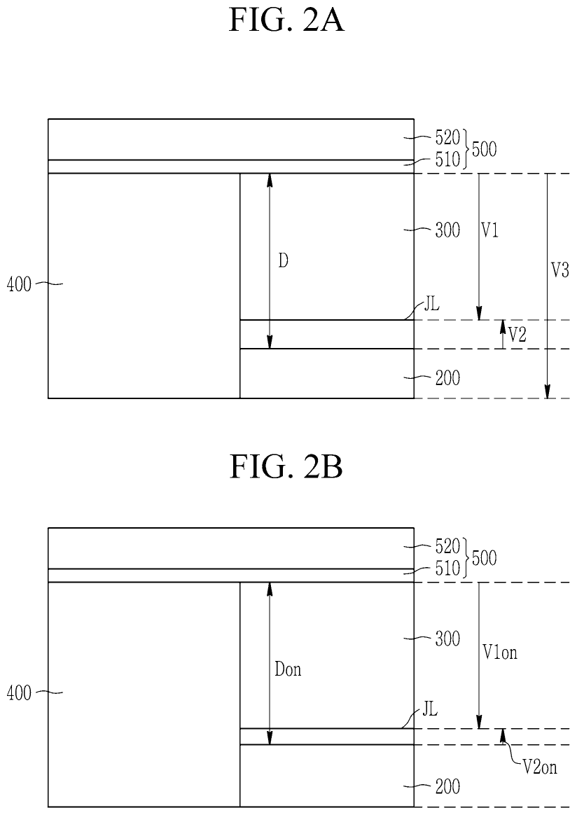

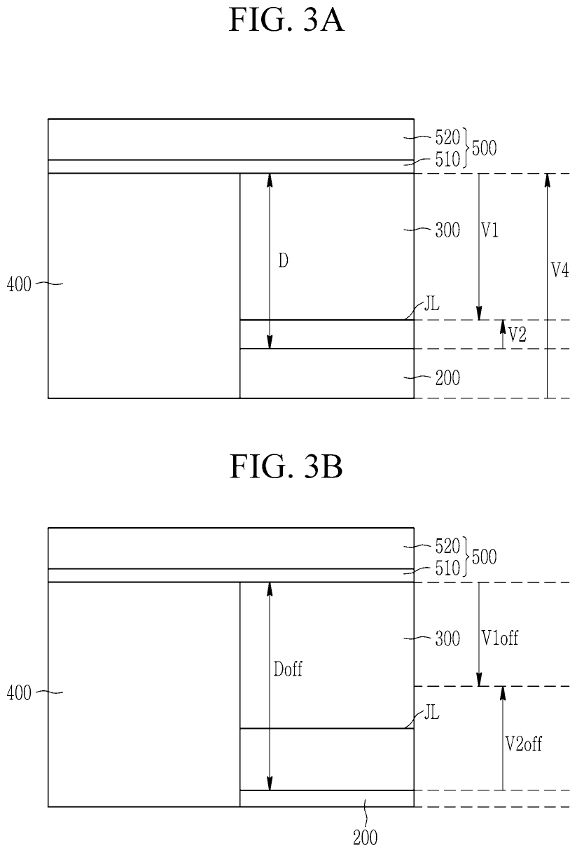

Next, an operation of the semiconductor device is described in detail with reference to FIG. 2, FIG. 3, and Table 1.

Operation conditions of the semiconductor device according to the present exemplary embodiment are as follows.

In the off state: V_{AK}<0 V

In the turn-on preparation state: 0 V<V_{AK}<Vₜᵤᵣₙ₋ₒₙ

In the on state: V_{AK}≥Vₜᵤᵣₙ₋ₒₙ

Here, V_{A} is a voltage applied to the anode, and V_{K} is a voltage applied to the cathode. Vₜᵤᵣₙ₋ₒₙ is a turn-on voltage of the semiconductor device, and V_{AK} means a value of V_{A}−V_{K}.

FIG. 2 and FIG. 3 are views showing an operation of the semiconductor device according to FIG. 1. FIG. 2 is a view showing the electric field in a state that the voltage is not applied to the semiconductor device according to FIG. 1 in the on state, and FIG. 3 a view showing the electric field in a state that the voltage is not applied to the semiconductor device according to FIG. 1 in the off state.

FIG. 2 and FIG. 3 show each electric field by enlarging the portion one of FIG. 1.

Referring to FIG. 2, (a) shows the electric field and the external electric field in the state that the voltage is not applied to the semiconductor device according to FIG. 1, and (b) shows an electric field direction of the on state of the semiconductor device according to FIG. 1.

In the state that the voltage is not applied to the semiconductor device, a depletion layer D is disposed below the PN junction line JL.

The internal electric field V1 due to the Schottky junction of the semiconductor device is formed in a PN junction line JL direction in the first electrode 500, and reaches the PN junction line JL below the first metal layer 510 of the first electrode 500.

The internal electric field V2 due to the PN junction of the semiconductor device is formed in the PN junction line JL direction on the end portion of the depletion layer D disposed below the PN junction line JL, and reaches the PN junction line JL from the end portion of the depletion layer D disposed below the PN junction line JL.

In the on state of the semiconductor device, the depletion layer Don is disposed under the PN junction line JL. In the instant case, the thickness of the depletion layer Don is thinner than the thickness of the depletion layer D in the state that the voltage is not applied to the semiconductor device.

In the on state of the semiconductor device, the external electric field V3 is formed in the second electrode 600 direction in the first electrode 500. Accordingly, if the semiconductor device enters the on state, the internal electric field V1on due to the Schottky junction is reinforced by the external electric field V3.

In the on state of the semiconductor device, the internal electric field V1on due to the Schottky junction reaches below the PN junction line JL under the first metal layer 510 of the first electrode 500. Accordingly, the internal electric field V2on due to the PN junction reaches only the place where the internal electric field V1on is formed due to the Schottky junction from the end portion of the depletion layer Don disposed below the PN junction line JL.

That is, by the reinforcement of the internal electric field V1on due to the Schottky junction according to the external electric field V3, the internal electric field V2on due to the PN junction in the on state of the semiconductor device becomes smaller than the internal electric field V2 due to the PN junction in the state that the voltage is not applied to the semiconductor device. Accordingly, the internal electric field due to the PN junction interfering with electron movement is weakened, and the internal electric field due to the Schottky junction guiding the electron movement is reinforced, a flow of the current is smooth. Accordingly, a current density is increased in the on state of the semiconductor device.

Referring to FIG. 3, (a) shows the electric field and the external electric field in the state that the voltage is not applied to the semiconductor device of FIG. 1, and (b) shows the electric field direction of the off state of the semiconductor device of FIG. 1.

In the state that the voltage is not applied to the semiconductor device, the depletion layer D, the internal electric field V1 due to the Schottky junction of the semiconductor device, and the internal electric field V2 due to the PN junction of the semiconductor device are the same as in the description of (a) of FIG. 2.

In the off state of the semiconductor device, the depletion layer Doff is disposed below the PN junction line JL. In the instant case, the thickness of the depletion layer Doff is thicker than the thickness of the depletion layer D in the state that the voltage is not applied to the semiconductor device.

The external electric field V4 in the on state of the semiconductor device is formed in the first electrode 500 direction in the second electrode 600. Accordingly, if the semiconductor device enters the off state, the internal electric field V2 off due to the PN junction is reinforced by the external electric field V4.

In the off state of the semiconductor device, the internal electric field V2 off due to the PN junction reaches the upper portion of the PN junction line JL from the end portion of the depletion layer Don disposed under the PN junction line JL. Accordingly, the internal electric field V1 off due to the Schottky junction only reaches the place where the internal electric field V2 off due to the PN junction is formed under the first metal layer 510 of the first electrode 500.

That is, by the reinforcement of the internal electric field V2off due to the PN junction according to the external electric field V4, the internal electric field V1off due to the Schottky junction in the off state of the semiconductor device is smaller than the internal electric field V1 due to the Schottky junction in the state that the voltage is not applied to the semiconductor device, however, because the voltage is divided and applied to the PN junction and the Schottky junction, it is largely maintained compared with a Schottky barrier diode (SBD) element in which only the Schottky junction exists. Accordingly, in the off state of the semiconductor device, the leakage current is reduced compared with the Schottky barrier diode element.

Next, characteristics of the semiconductor device according to the present exemplary embodiment and a conventional semiconductor device are compared and described with reference to Table 1.

Table 1 shows an operation simulation result of the semiconductor device according to the present exemplary embodiment and the conventional semiconductor device.

Comparative Example 1 is the conventional Schottky barrier diode (SBD) element, and Comparative Example 2 is a conventional junction barrier Schottky (JBS) diode element.

TABLE 1

| | Comparative | Comparative | Exemplary |
|---|---|---|---|
| | Example 1 | Example 2 | embodiment |
| Current density at 1.5 V | 273.7 | 224.3 | 311.7 |
| (A/cm²) | | | |
| Breakdown voltage (V) | 1858 | 1710 | 2707 |
| Leakage current density at | 16.52 | 9.61 | 10.04 |
| 1200 V (mA/cm²) | | | |
| Element area (cm²) of 100 A | 0.365 | 0.446 | 0.321 |
| Element reference leakage | 60.3 | 42.8 | 32.2 |
| current (μA) of 100 A | | | |

Referring to Table 1, in the case of the semiconductor device according to the present exemplary embodiment compared with the diode element of Comparative Example 1, it may be confirmed that the current density is increased by 13.8% and the leakage current density is reduced by 39.2%. In the case of the semiconductor device according to the present exemplary embodiment compared with the diode element of Comparative Example 2, it may be confirmed that the current density is increased by 38.9%.

In the case of the semiconductor device according to the exemplary embodiment of the present invention, it may be confirmed that the element area is reduced by 12% compared with the diode element of Comparative Example 1, and the element area is reduced by 28% compared with the diode element of Comparative Example 2. Accordingly, for the semiconductor device according to the exemplary embodiment of the present invention, a cost reduction of the semiconductor device is possible through increasing a number of semiconductor devices per unit wafer and a yield improvement.

Also, in the case of the semiconductor device according to the exemplary embodiment of the present invention, it may be confirmed that the leakage current is reduced by 46% in the element area realizing the same current compared with the diode element of Comparative Example 1, and the leakage current is reduced by 24.7% in the element area realizing the same current compared with the diode element of Comparative Example 2. Accordingly, the semiconductor device according to the present exemplary embodiment of the present invention reduces a power loss in the off state.

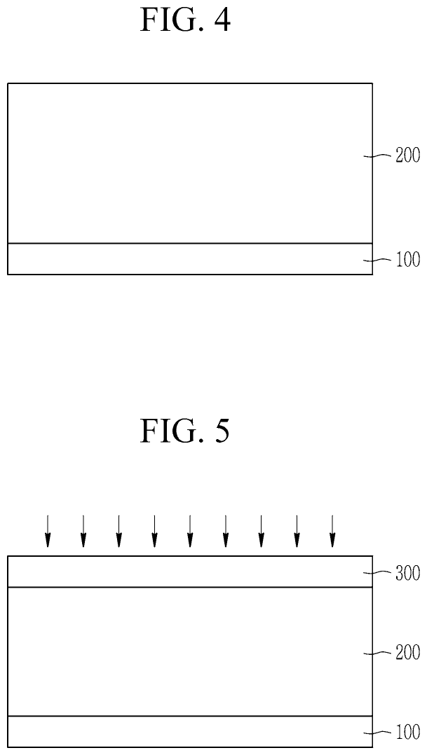

Next, the manufacturing method of the semiconductor device according to an exemplary embodiment of the present invention is described with reference to FIG. 4, FIG. 5, and FIG. 6, and FIG. 1.

FIG. 4, FIG. 5, and FIG. 6 are views schematically showing an example of a manufacturing method of a semiconductor device according to an exemplary embodiment of the present invention.

Referring to FIG. 4, the substrate 100 is prepared, and the n− type of layer 200 is formed on the first surface of the substrate 100. Here, the substrate 100 may be the n+ type of silicon carbide substrate, and the n− type of layer 200 may be formed by epitaxial growth.

Referring to FIG. 5, the p− type of region 300 is formed on the n− type of layer 200. The p− type of region 300 may be formed by injecting a p type of ion such as boron (B), aluminum (Al), gallium (Ga), and indium (In) to a portion of the n− type of layer 200. Also, it is not limited thereto, and the p− type of region 300 may be formed by epitaxial growth on the n− type of layer 200. Here, the p− type of region 300 and the n− type of layer 200 are in contact with each other such that the PN junction is formed in the boundary surface.

Referring to FIG. 6, the p+ type of region 400 is formed on the side of the p− type of region 300. The p+ type of region 400 is formed at the top portion of the n− type of layer 200 and is in contact with the p− type of region 300. The p+ type of region 400 may be formed by injecting a p type of ion such as boron (B), aluminum (Al), gallium (Ga), and indium (In) to a portion of the p− type of region 300 and the n− type of layer 200. Here, the ion doping concentration of the p+ type of region 400 is higher than the ion doping concentration of the p− type of region 300. Also, the thickness of the p+ type of region 400 is thicker than the thickness of the p− type of region 300. On the other hand, it is not limited thereto, and the thickness of the p+ type of region 400 may be the same as the thickness of the p− type of region 300.

Referring to FIG. 1, the first metal layer 510 and the second metal layer 520 are sequentially formed on the p− type of region 300 and the p+ type of region 400, and the second electrode 600 is formed on the second surface of the n+ type of silicon carbide substrate 100. Here, the first metal layer 510 and the second metal layer 520 may form the first electrode 500. Also, the first metal layer 510 is in contact with the p− type of region 300, the Schottky junction is formed in the boundary surface therebetween. The first metal layer 510 and the p− type of region 300 are in continuous contact. That is, the first metal layer 510 is not in contact with the n− type of layer 200.

The first metal layer 510 may include the Schottky metal, and the second metal layer 520 and the second electrode 600 may include the ohmic metal.

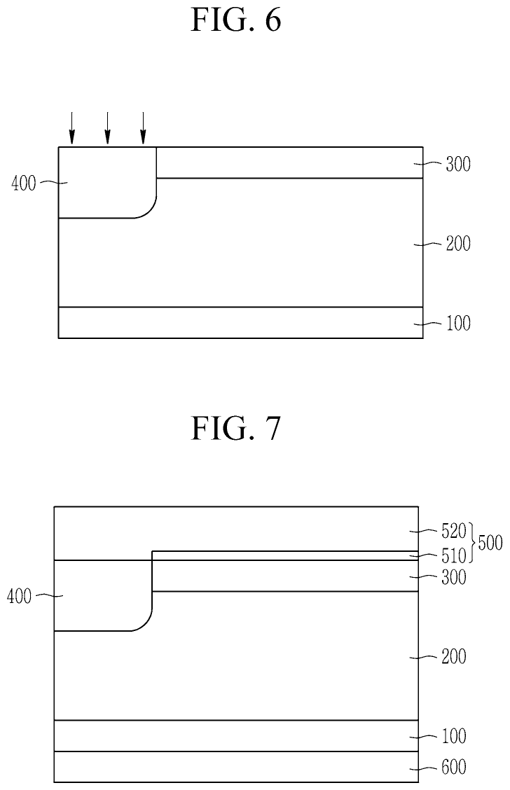

The semiconductor device according to various exemplary embodiments of the present invention is described with reference to FIG. 7.

FIG. 7 is a schematic view showing an example of a cross-section of a semiconductor device according to various exemplary embodiments of the present invention.

Referring to FIG. 7, the semiconductor device according to the present exemplary embodiment of the present invention is the same as the semiconductor device of FIG. 1, except for the structure of the first electrode 500. The description for the same structures is omitted.

The first electrode 500 is disposed on the p− type of region 300 and the p+ type of region 400, and includes the first metal layer 510 and the second metal layer 520. The first metal layer 510 may include the Schottky metal, and the second metal layer 520 may include the ohmic metal.

The first metal layer 510 is disposed on the p− type of region 300, and the second metal layer 520 is disposed on the p+ type of region 400 and the first metal layer 510. Here, the first metal layer 510 is in contact with the p-type of region 300 such that the Schottky junction is formed in the boundary surface therebetween. The first metal layer 510 and the p-type of region 300 are in continuous contact. That is, the first metal layer 510 is not in contact with the n-type of layer 200. The second metal layer 520 is in contact with the p+ type of region 400 such that the ohmic junction is formed in the boundary surface therebetween.

For convenience in explanation and accurate definition in the appended claims, the terms “upper”, “lower”, “inner”, “outer”, “up”, “down”, “upper”, “lower”, “upwards”, “downwards”, “front”, “rear”, “back”, “inside”, “outside”, “inwardly”, “outwardly”, “internal”, “external”, “inner”, “outer”, “forwards”, and “backwards” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the present invention to the precise forms disclosed, and obviously many modifications and variations are possible in light of the above teachings. The exemplary embodiments were chosen and described, to explain certain principles of the and their practical application, to enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A semiconductor device comprising:
an n− type of layer disposed at a first surface of a substrate;
a p− type of region and a p+ type of region disposed at a top portion of the n− type of layer;
a first electrode disposed on the p− type of region and the p+ type of region; and
a second electrode disposed at a second surface of the substrate,
wherein the first electrode includes a first metal layer disposed on the p− type of region and a second metal layer disposed on the first metal layer, and
wherein the first metal layer is in continuous contact with the p− type of region.

2. The semiconductor device of claim 1, wherein an ion doping concentration of the p+ type of region is higher than an ion doping concentration of the p− type of region.

3. The semiconductor device of claim 2, wherein the p− type of region and the p+ type of region are in contact with each other.

4. The semiconductor device of claim 3, wherein a thickness of the p+ type of region between the substrate and the first electrode is thicker than a thickness of the p− type of region between the substrate and the first electrode.

5. The semiconductor device of claim 4,
wherein the first metal layer includes a Schottky metal, and
wherein the second metal layer and the second electrode include an ohmic metal.

6. The semiconductor device of claim 5, wherein the first metal layer is disposed and extends on the p+ type of region.

7. The semiconductor device of claim 6, wherein the first metal layer is in contact with the p− type of region to form a Schottky junction in a boundary surface therebetween, and is in contact with the p+ type of region to form an ohmic junction in a boundary surface therebetween.

8. The semiconductor device of claim 5, wherein the second metal layer is disposed on the p+ type of region.

9. The semiconductor device of claim 8,
wherein the first metal layer is in contact with the p− type of region to form a Schottky junction in a boundary surface therebetween, and
wherein the second metal layer is in contact with the p+ type of region to form an ohmic junction in a boundary surface therebetween.

10. The semiconductor device of claim 1, wherein the substrate is an n+ type of silicon carbide substrate.

11. A method for manufacturing a semiconductor device, the method comprising:
forming an n− type of layer in a first surface of a substrate;
forming a p− type of region and a p+ type of region in a top portion of the n− type of layer;
forming a first electrode on the p− type of region and the p+ type of region; and
forming a second electrode in a second surface of the substrate,
wherein the first electrode includes a first metal layer disposed on the p− type of region and a second metal layer disposed on the first metal layer, and
wherein the first metal layer is in continuous contact with the p− type of region.

12. The method of claim 11, wherein an ion doping concentration of the p+ type of region is higher than an ion doping concentration of the p− type of region.

13. The method of claim 12, wherein the p− type of region and the p+ type of region are in contact with each other.

14. The method of claim 13, wherein a thickness of the p+ type of region between the substrate and the first electrode is thicker than a thickness of the p− type of region between the substrate and the first electrode.

15. The method of claim 14,
wherein the first metal layer includes a Schottky metal, and
wherein the second metal layer and the second electrode include an ohmic metal.

16. The method of claim 15, wherein the first metal layer is disposed and extends on the p+ type of region.

17. The method of claim 16, wherein the first metal layer is in contact with the p− type of region to form a Schottky junction in a boundary surface therebetween, and is in contact with the p+ type of region to form an ohmic junction in a boundary surface therebetween.

18. The method of claim 15, wherein the second metal layer is disposed on the p+ type of region.

19. The method of claim 18,
wherein the first metal layer is in contact with the p− type of region to form a Schottky junction in a boundary surface therebetween, and
wherein the second metal layer is in contact with the p+ type of region to form an ohmic junction in a boundary surface therebetween.

20. The method of claim 11, wherein the substrate is an n+ type of silicon carbide substrate.
